(19) United States
(12) Patent Application Publication
(10) Pub. No.: US 2008/0251785 A1
(43) Pub. Date: Oct. 16, 2008

(54) Display device and method of fabricating the same

(76) Inventors: Ji-yong Noh, Suwon-si (KR); Moo-jin Kim, Suwon-si (KR); Dae-woo Lee, Suwon-si (KR); Jang-soon Im, Suwon-si (KR); Kyoung-bo Kim, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 11/907,874

(22) Filed: Oct. 18, 2007

(30) Foreign Application Priority Data
Apr. 12, 2007 (KR) 10-2007-0036063

(51) Int. Cl. H01L 51/50; H01L 21/84

(52) U.S. Cl. 257/40; 438/29; 257/E51.018; 257/E21.411

(57) ABSTRACT

A display device includes a thin film transistor (TFT) on a substrate, the TFT including source/drain electrodes, a cover layer on the source/drain electrodes, and a light source including at least one electrode, the electrode being electrically connected to the source/drain electrodes of the TFT through the cover layer, wherein the cover layer includes a same material as the electrode of the light source.

### BACKGROUND OF THE INVENTION

1. Field of the Invention

Embodiments of the present invention relate to a display device and a method of fabricating the same. More particularly, embodiments of the present invention relate to a display device having improved brightness uniformity and a method of fabricating the same.

2. Description of the Related Art

A display device, e.g., an electroluminescent (EL) display device, may include a substrate, a thin film transistor (TFT) on the substrate, and a light source, e.g., a light emitting diode (LED), electrically connected to the TFT. More specifically, the TFT may include a semiconductor layer, a gate electrode, and source/drain electrodes on the substrate. The light source may be electrically connected to any one of the source/drain electrodes of the TFT.

During fabrication of the display device, the electrical connection between the light source and the source/drain electrodes of the TFT may require exposure of a surface of the source/drain electrodes to, e.g., moisture, oxygen, and other impurities, thereby generating an impurity layer on the source/drain electrodes. Existence of impurities on the source/drain electrodes, e.g., an oxidized layer, may cause reduced adhesion and increased contact resistance between the source/drain electrodes and the light source. As a result, an interface between the source/drain electrodes and the light source may be uneven, thereby reducing brightness uniformity of the display device.

### SUMMARY OF THE INVENTION

The present invention is therefore directed to a display device and a method of fabricating the same, which substantially overcome one or more of the problems due to the limitations and disadvantages of the related art.

It is therefore a feature of an embodiment of the present invention to provide a display device with reduced contact resistance and enhanced adhesion between a thin film transistor and a light source thereof.

It is therefore another feature of an embodiment of the present invention to provide a display device with improved brightness uniformity.

It is yet another feature of an embodiment of the present invention to provide a method of fabricating a display device having one or more of the above features.

At least one of the above and other features of the present invention may be realized by providing a display device, including a thin film transistor (TFT) on a substrate, the TFT including source/drain electrodes, a cover layer on the source/drain electrodes, and a light source including at least one electrode, the electrode being electrically connected to at least one of the source/drain electrodes of the TFT through the cover layer, wherein the cover layer includes a same material as the electrode of the light source. The light source may be a light emitting diode. The display device may be an organic electroluminescent display device.

The electrode of the light source may include a single-layer conductive film. The electrode of the light source may be transparent. The electrode of the light source may include one or more of indium-tin-oxide, indium-zinc-oxide, indium-zinc-tin-oxide, indium-cesium-oxide, and/or indium-tungsten-oxide. Alternatively, the electrode of the light source may include a multi-layer structure, the multi-layer structure having a bottom layer connected to the source/drain electrodes. The cover layer may include a same material as the bottom layer of the multi-layer structure. The first electrode of the light source may have a structure of ITO/Ag/ITO, ITO/Al/ITO, ITO/AlNiLa/ITO, or ITO/AlNiLa.

The source/drain electrodes may include one or more of aluminum, molybdenum tungsten, molybdenum, copper, silver, and/or alloys thereof. The source/drain electrodes may include a multi-layer structure of MoW/AlNd/MoW, Ti/Cu/Ti, and/or Ti/Al/Ti. The cover layer may have a thickness of about 30 angstroms to about 50 angstroms. The cover layer may be directly on the source/drain electrodes. The cover layer may entirely overlap with the source/drain electrodes. The cover layer may be non-continuous.

At least one of the above and other features of the present invention may be further realized by providing a method of fabricating a display device, including forming a thin film transistor (TFT) on a substrate, the TFT including source/drain electrodes, forming a cover layer on the source/drain electrodes, and forming a light source including at least one electrode, the electrode being electrically connected to the source/drain electrodes of the TFT through the cover layer, wherein the cover layer includes a same material as the electrode of the light source.

Forming the TFT may include forming the source/drain electrodes by depositing a first conductive layer on the substrate in a first chamber, and forming the cover layer may include depositing a second conductive layer on the first conductive layer in the first chamber. Forming the light source may include forming the at least one electrode by depositing a third conductive layer on the second conductive layer in a second chamber, the second chamber being different than the first chamber. Forming the light source may include forming a light emitting diode. The cover layer and the electrode of the light source may be formed of a same conductive material, the conductive material including one or more of indium-tin-oxide, indium-zinc-oxide, indium-zinc-tin-oxide, indium-cesium-oxide, and/or indium-tungsten-oxide.

### BRIEF DESCRIPTION OF THE DRAWINGS

The above and other features and advantages of embodiments will become more apparent to those of ordinary skill in the art by describing in detail exemplary embodiments thereof with reference to the attached drawings, in which:

FIG. 1 illustrates a cross sectional view of an electroluminescent (EL) display device according to an embodiment of the present invention;

FIGS. 2A-2C illustrate cross sectional views of sequential stages in a method of fabricating an EL display device according to an embodiment of the present invention;

FIG. 3 illustrates a cross sectional view of an EL display device according to another embodiment of the present invention;

FIG. 4 illustrates a cross sectional view of an EL display device according to another embodiment of the present invention;

FIG. 5 illustrates a cross sectional view of an EL display device according to another embodiment of the present invention;

FIG. 6 illustrates a cross sectional view of an EL display device according to another embodiment of the present invention; and

FIGS. 7A-7B illustrate transmission electron microscope (TEM) photographs of an interface between a first electrode and a source/drain electrode of a conventional EL display device and an EL display device according to an embodiment of the present invention, respectively.

### DETAILED DESCRIPTION OF THE INVENTION

Korean Patent Application No. 2007-0036063, filed on Apr. 12, 2007, in the Korean Intellectual Property Office, and entitled: “Light Emitting Display Device and Method of Fabricating the Same,” is incorporated by reference herein in its entirety.

Embodiments of the present invention will now be described more fully hereinafter with reference to the accompanying drawings, in which exemplary embodiments of the invention are illustrated. Aspects of the invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another element or substrate, it can be directly on the other element or substrate, or intervening layers or elements may also be present. Further, it will be understood that when a layer or element is referred to as being “under” another element, it can be directly under, or one or more intervening layers or elements may also be present. In addition, it will also be understood that when a layer or element is referred to as being “between” two layers or elements, it can be the only layer or element between the two layers or elements, or one or more intervening layers or elements may also be present. Like reference numerals refer to like elements throughout.

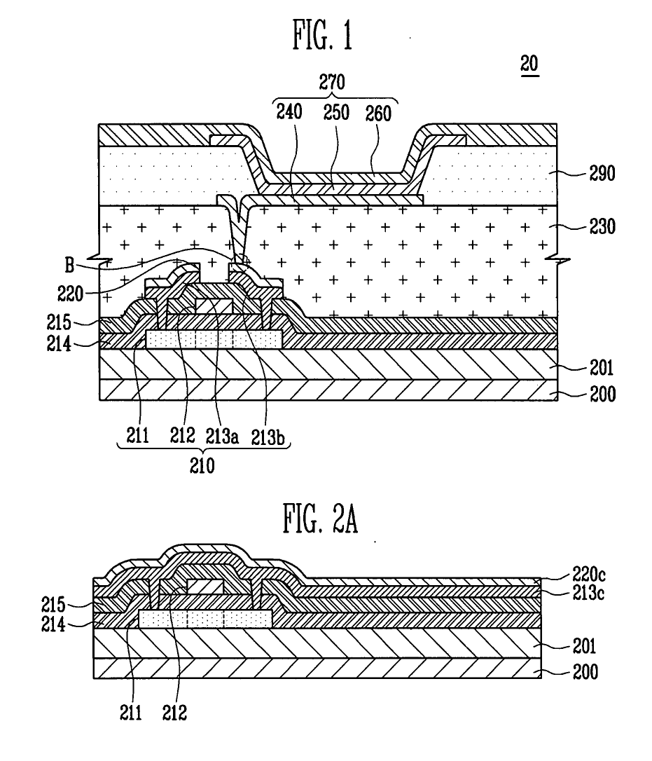

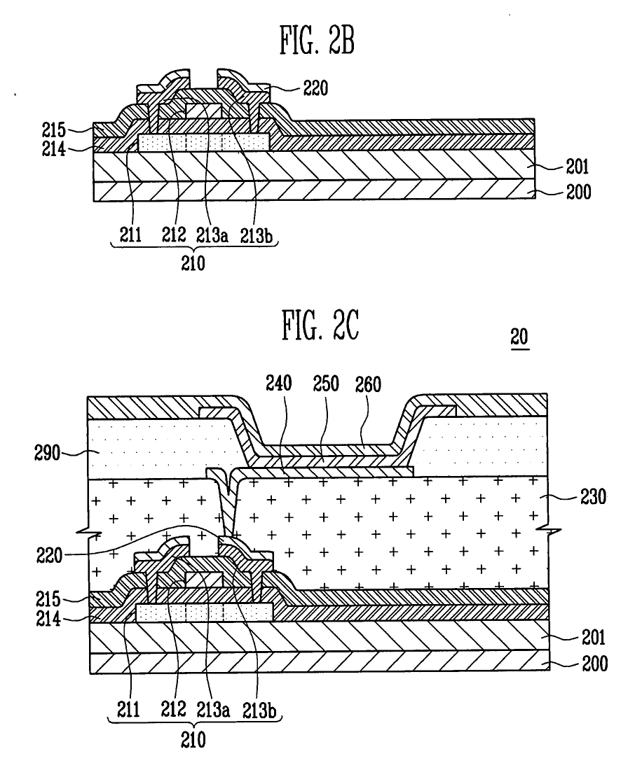

An exemplary embodiment of a display device according to the present invention will now be described more fully with reference to FIGS. 1 and 2A-2C. It should be noted, however, that even though embodiments of the present invention are illustrated with respect to an electroluminescent (EL) display device, other types of display devices, e.g., a liquid crystal display (LCD), a field emission display (FED), a plasma display panel (PDP), a vacuum fluorescent display (VFD), and so forth, are within the scope of the present invention.

As illustrated in FIGS. 1 and 2A-2B, an EL display device 20 may include a substrate 200, a thin film transistor (TFT) 210 on the substrate 200, a light emitting diode (LED) 270 on the TFT 210, and a cover layer 220 between the TFT 210 and the LED 270. The EL display device 20 may further include a planarization layer 230 between the TFT 210 and the LED 270.

The TFT 210 of the EL display device 20 may include a semiconductor layer 211, a gate electrode 212, and source/drain electrodes 213a and 213b on the substrate 200. The semiconductor layer 211 may include a channel region between source/drain regions, and a gate insulating layer 214 may be formed thereon.

The gate electrode 212 of the TFT 210 may be formed on the gate insulating layer 214 and above the channel region of the semiconductor layer 211 in a predetermined pattern. The gate electrode 212 may be formed of a conductive metal, e.g., aluminum (Al), molybdenum tungsten (MoW), molybdenum (Mo), copper (Cu), silver (Ag), silver alloy, aluminum alloy, and so forth. An inter insulating layer 215 may be formed on the gate electrode 212 of a same material as the gate insulating layer 214.

The source/drain electrodes 213a and 213b of the TFT 210 may be formed on the inter insulating layer 215, and may be electrically connected to the source/drain regions of the semiconductor layer 211 via a contact hole through the gate insulating layer 214 and the inter insulating layer 215. The source/drain electrodes 213a and 213b may be formed of a conductive metal, e.g., aluminum (Al), molybdenum tungsten (MoW), molybdenum (Mo), copper (Cu), silver (Ag), silver alloy, aluminum alloy, indium-tin-oxide (ITO), and so forth.

The LED 270 of the EL display device 20 may include a first electrode 240, a second electrode 260, and a light emitting layer 250 therebetween. The first electrode 240 may be electrically connected to one of the source/drain electrodes 213a and 213b of the TFT 210. If the LED 270 is a rear-type LED, the first electrode 240 may be formed of a transparent conductive material, e.g., ITO, indium-zinc-oxide (IZO), indium-zinc-tin-oxide (IZTO), indium-cesium-oxide (ICO), and/or indium-tungsten-oxide (IWO), and so forth. If the LED 270 is a front-type LED, the first electrode 240 may include a reflective layer on the transparent conductive material. The reflective layer may exhibit a reflexibility of at least about 60%, and may be formed of one or more of aluminum (Al), silver (Ag), or an alloy thereof. The light emitting layer 250 may have a multi-layer structure, and may include an electron injecting layer, an electron transporting layer, an emission layer, a hole injecting layer, and a hole transporting layer. The light emitting layer 250 may be formed of an organic material, so that the LED 270 may be an organic light emitting diode (OLED). The second electrode 260 may be formed of a substantially same material as the first electrode 240, and may be formed of a transparent material if the LED 270 is a front-type LED.

The cover layer 220 of the EL display device 20 may be formed on each of the source/drain electrodes 213a and 213b of a substantially same material as the first electrode 240 of the LED 270. The cover layer 220 may be a thin film having a substantially uniform thickness and a same length as the source/drain electrodes 213a and 213b. The cover layer 220 may entirely overlap with and cover an upper surface of each of the source/drain electrodes 213a and 213b. The cover layer 220 may be in direct or indirect contact with the source/drain electrodes 213a and 213b. The cover layer 220 may be non-continuous, i.e., a layer having at least two discrete segments.

Since the cover layer 220 may be formed on the source/drain electrodes 213a and 213b, and in a same chamber as the source/drain electrodes 213a and 213b, impurities, e.g., oxidation of the source/drain electrodes 213a and 213b, on the source/drain electrodes 213a and 213b may be minimized or prevented. Accordingly, adhesion between the source/drain electrodes 213a and 213b and the first electrode 240 may be enhanced without increasing a contact resistance therebetween. As a result, an interface between the source/drain electrodes 213a and 213b and the first electrode 240 may be uniform, thereby increasing brightness uniformity of the EL display device 20.

The EL display device 20 may further include a pixel defining layer 290 on the planarization layer 230 to separate between the first electrode 240 and the light emitting layer 250. The pixel defining layer 290 may include an opening (not shown) to at least partially expose the first electrode 240. The second electrode 260 of the LED 270 may be formed in contact with the pixel defining layer 290.

The EL display device 20 may operate as follows. Holes may be injected into the hole injecting layer of the light emitting layer 250 from the first electrode 240, and the injected holes may be transported through the hole transporting layer into the emission layer of the light emitting layer 250. Similarly, electrons may be injected into the electron injecting layer of the light emitting layer 250 from the second electrode 260, and the injected electrons may be transported to the emission layer of the light emitting layer 250 through the electron transporting layer of the light emitting layer 250. The holes and electrons may be coupled in the emission layer of the light emitting layer 250 to form excitons. When the excitons fall to a lower energy level, the emission layer of the light emitting layer 250 may emit light.

A fabrication process of the EL display device 20 will be described in detail bellow with reference to FIGS. 2A-2C.

As illustrated in FIG. 2A, the substrate 200 may be provided, followed by depositing thereon a buffer layer 201. The substrate 200 may be moved into a first chamber (not shown) to form the TFT 210 on the buffer layer 201.

The semiconductor layer 211 of the TFT 210 may be formed of, e.g., silicon or organic material, on the buffer layer 201 in a predetermined pattern. More specifically, the semiconductor layer 211 may be formed by, e.g., chemical vapor deposition (CVD), to a thickness of about 300 angstroms to about 2000 angstroms, followed by patterning to a predetermined pattern. The gate insulating layer 214 may be formed on the substrate 200 to coat upper surfaces of the semiconductor layer 211 and of the buffer layer 201, as illustrated in FIG. 2A.

The gate electrode 212 may be formed in a predetermined pattern on the gate insulating layer 214 to correspond to the channel region of the semiconductor layer 211, e.g., above a central region of the semiconductor layer 211. More specifically, the gate electrode 212 may be formed by depositing a conductive metal, e.g., aluminum (Al), molybdenum tungsten (MoW), molybdenum (Mo), copper (Cu), silver (Ag), or an alloy thereof, on the gate insulating layer 214 by, e.g., sputtering, to a thickness of about 2000 angstroms to about 3000 angstroms. Next, the inter insulating layer 215 may be formed to cover the gate electrode 212 and the gate insulating layer 214. The inter insulating layer 215 and the gate insulating layer 214 may be formed by a substantially similar method.

The source/drain electrodes 213a and 213b may be formed on the inter insulating layer 215. More specifically, a first conductive layer 213c may be deposited on the inter insulating layer 215 by, e.g., sputtering, to a thickness of about 1500 angstroms. The first conductive layer 213c may cover the entire inter insulating layer 215, and may be electrically connected to the source/drain regions of the semiconductor layer 211 via respective contact holes, i.e., openings formed through the gate insulating layer 214 and the inter insulating layer 215. The first conductive layer 213c may have a single-layer structure or a multi-layer structure. If the first conductive layer 213c has a single-layer structure, a layer including one or more of, e.g., aluminum (Al), molybdenum tungsten (MoW), molybdenum (Mo), copper (Cu), silver (Ag), ITO, titanium (Ti), neodymium (Nd) and/or an alloy thereof, may be formed on the inter insulating layer 215 to a thickness of about 1500 angstroms. If the first conductive layer 213c has a multi-layer structure, a plurality of layers may be deposited on the inter insulating layer 215 to form a stacked-structure, e.g., MoW/AlNd/MoW, Ti/Cu/Ti, and/or Ti/Al/Ti, having a thickness of, e.g., about 500/4000/500 angstroms.

Next, a second conductive layer 220c may be deposited on the first conductive layer 213c to a thickness of about 30 angstroms to about 50 angstroms. When the thickness of the second conductive material 220c is below about 30 angstroms, deposition of the second conductive layer 220c may be non-uniform. The second conductive layer 220c may be deposited in the first chamber (not shown), i.e., in a same chamber as the first conductive layer 213c, by, e.g., an in-situ method. Deposition of the first and second conductive layers 213c and 220c in a same chamber may minimize or prevent exposure of the first conductive layer 213c to oxidizing elements, e.g., oxygen and/or moisture, thereby reducing accumulation of impurities on the first conductive layer 213c.

Then, as illustrated in FIG. 2B, the first and second conductive layers 213c and 220c may be patterned to form the source/drain electrodes 213a and 213b and the cover layer 220, respectively. The first and second conductive layers 213c and 220c may be patterned so that the cover layer 220 may completely overlap with each of the source/drain electrodes 213a and 213b. For example, the cover layer 220 may include two discrete segments, so each discrete segment may have a substantially same length as the source/drain electrodes 213a and 213b in order to coat an upper surface of the source/drain electrodes 213a and 213b, as illustrated in FIG. 2B.

Subsequently, the substrate 200 may be moved to a second chamber, i.e., a chamber other than the first chamber. Then, as illustrated in FIG. 2C, the planarization layer 230 may be formed on the substrate 200 by depositing, e.g., acrylic, polyimide, and/or benzocyclobutene (BCB), thereon. A via hole may be formed by, e.g., etching, through the planarization layer 230 to contact either one of the source/drain electrodes 213a and 213b. Next, the LED 270 may be formed on the planarization layer 230 and in electrical communication with either one of the source/drain electrodes 213a and 213b through the via hole.

More specifically, the first electrode 240 of the LED 270 may be formed on the planarization layer 230 and in electrical communication with one of the source/drain electrodes 213a and 213b through the via hole, as illustrated in FIG. 2C. If the LED 270 is a rear-type LED, the first electrode 240 may be formed by, e.g., sputtering, on the planarization layer 230 and in the via hole a transparent conductive material, e.g., ITO, IZO, IZTO, ICO, and/or IWO, to a thickness of about 1200 angstroms. If the LED 270 is a front-type LED, the first electrode 240 may be formed by depositing, e.g., by sputtering, a multi-layered structure, e.g., ITO/Ag/ITO, ITO/Al/ITO, ITO/AlNiLa/ITO, and/or ITO/AlNiLa, on the planarization layer 230 and in the via hole to a thickness of, e.g., about 70/1000/70 angstroms.

Next, the pixel defining layer 290 may be formed by depositing an organic insulating material, e.g., acrylic, polyamide, and so forth, on the planarization layer 230. The organic insulating material may be exposed, developed, and etched to form a non-continuous layer, so that an upper surface of the first electrode 240 may be partially exposed. Then, the light emitting layer 250 of the LED 270 may be formed on the exposed upper surface of the first electrode 240, followed by formation of the second electrode 260 on the light emitting layer 250 and in contact with the pixel defining layer 290, as illustrated in FIG. 2C.

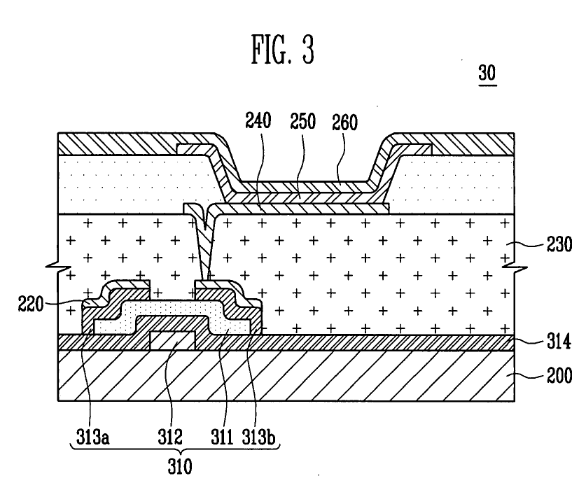

According to another embodiment illustrated in FIG. 3, an EL display device 30 may be substantially similar to the EL display device 20 with the exception of having a TFT 310 instead of the TFT 210. More specifically, the TFT 310 may be substantially similar to the TFT 210 with the exception of having a gate electrode 312 formed directly on the substrate 200, and a gate insulating layer 314, a semiconductor layer 311, and source/drain electrodes 313a and 313b formed sequentially on the gate electrode 312. In this respect, it is noted that the source/drain electrodes 313a and 313b may be in direct contact with the semiconductor layer 211, and therefore, no via holes through insulating layers are required. The methods and materials employed to form components of the TFT 310 may be substantially similar to the methods and materials employed to form the TFT 210 described previously with respect to FIGS. 1 and 2A-2C, and therefore, will not be repeated herein.

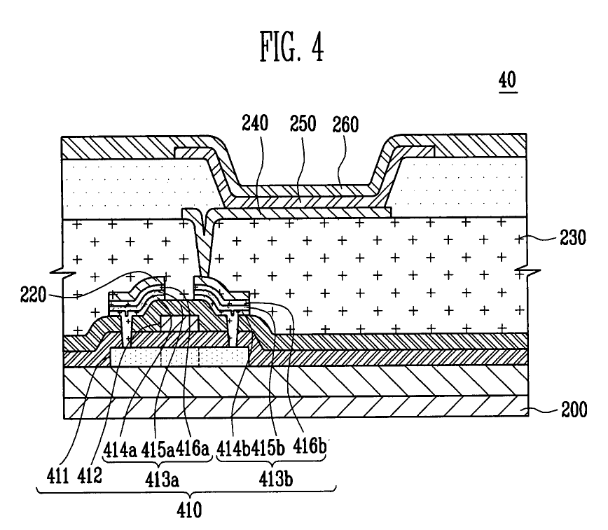

According to yet another embodiment illustrated in FIG. 4, an EL display device 40 may be substantially similar to the EL display device 20 with the exception of having source/drain electrodes 413a and 413b instead of the source/drain electrodes 213a and 213b. More specifically, source/drain electrodes 413a and 413b may include a multi-layered structure. For example, the source electrode 413a may include first, second, and third sub-layers 414a, 415a, and 416a, respectively, and the drain electrode 413b may include fourth, fifth, and sixth sub-layers 414b, 415b, and 416b, respectively. Accordingly, each of the source/drain electrodes 413a and 413b may have a structure including, e.g., MoW/AlNd/MoW, Ti/Cu/Ti, and/or Ti/Al/Ti.

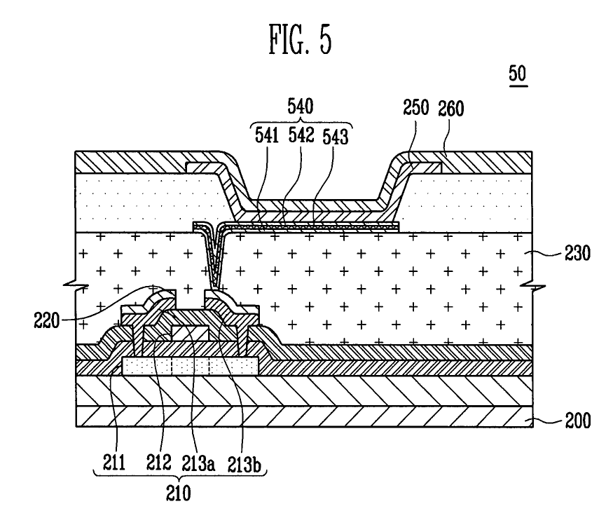

According to still another embodiment illustrated in FIG. 5, an EL display device 50 may be substantially similar to the EL display device 20 with the exception of having a LED 570 instead of the LED 270. More specifically, the LED 570 may include a first electrode 540 having a multi-layered structure, the light emitting layer 250, and the second electrode 260. For example, the first electrode 540 may include first, second, and third films 541, 542, 543, respectively. Accordingly, the first electrode 540 may have a structure including, e.g., ITO/Ag/ITO, ITO/Al/ITO, ITO/AlNiLa/ITO, and so forth. In another example, the first electrode 540 may include a double-layer structure, e.g., ITO/AlNiLa.

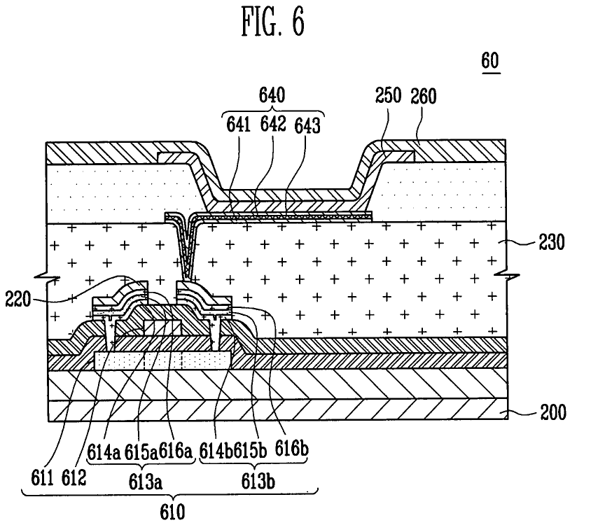

According to yet another embodiment illustrated in FIG. 6, an EL display device 60 may be substantially similar to the EL display device 50 with the exception of having source/drain electrodes 613a and 613b instead of the source/drain electrodes 213a and 213b. More specifically, source/drain electrodes 613a and 613b may include a multi-layered structure. For example, the source electrode 613a may include first, second, and third sub-layers 614a, 615a, and 616a, respectively, and the drain electrode 413b may include fourth, fifth, and sixth sub-layers 614b, 615b, and 616b, respectively. Accordingly, each of the source/drain electrodes 613a and 613b may have a structure including, e.g., MoW/AlNd/MoW, Ti/Cu/Ti, and/or Ti/Al/Ti. It is further noted that the structure of the TFT 210 may be modified to correspond to the structure of the TFT 310 described previously with respect to FIG. 3.

### EXAMPLE

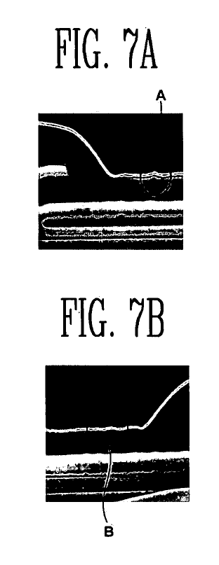

The EL display device 20 was compared to a conventional EL display device, i.e., an EL display device having no cover layer 220 on the source/drain electrodes. More specifically, a transmission electron microscope (TEM) photograph was taken of an interface between a first electrode of a LED and source/drain electrodes of a TFT of each EL display device. Both EL display devices were fabricated of substantially identical materials with the exception of the cover layer 220. FIG. 7A illustrates a TEM photograph of the conventional EL display device, and FIG. 7B illustrates a TEM photograph of the EL display device 20.

As illustrated in region “A” of FIG. 7A, a thin layer of impurities, e.g., an oxidized surface of the source/drain electrode, was generated on the source/drain electrode. As further illustrated in region “A” of FIG. 7A, a “bump” was generated in the interface between the source/drain electrode and the LED.

On the other hand, as illustrated in region “B” of FIG. 7B, no impurities layer or “bumps” were generated in the interface between the source/drain electrodes 213a and 213b and the LED 270, i.e., the interface between the source/drain electrodes 213a and 213b and the LED 270 was substantially flat.

Embodiments of the present invention may be advantageous in providing an EL display device structure having improved adhesive property and reduced contact resistance between a TFT and a LED via a cover layer therebetween. Such a structure may minimize or prevent oxidation of the source/drain electrodes of the TFT, thereby providing an EL display device with high resolution and improved brightness uniformity, i.e., reduced number of dark spots.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A display device, comprising:
a thin film transistor (TFT) on a substrate, the TFT including source/drain electrodes;
a cover layer on the source/drain electrodes; and
a light source including at least one electrode, the electrode being electrically connected to at least one of the source/drain electrodes of the TFT through the cover layer,
wherein the cover layer includes a same material as the electrode of the light source.

2. The display device as claimed in claim 1, wherein the electrode of the light source includes a single-layer conductive film.

3. The display device as claimed in claim 2, wherein the electrode of the light source is transparent.

4. The display device as claimed in claim 3, wherein the electrode of the light source includes one or more of indium-tin-oxide, indium-zinc-oxide, indium-zinc-tin-oxide, indium-cesium-oxide, and/or indium-tungsten-oxide.

5. The display device as claimed in claim 1, wherein the electrode of the light source includes a multi-layer structure, the multi-layer structure having a bottom layer connected to the source/drain electrodes.

6. The display device as claimed in claim 5, wherein the cover layer includes a same material as the bottom layer of the multi-layer structure.

7. The display device as claimed in claim 5, wherein the first electrode of the light source has a structure of ITO/Ag/ITO, ITO/Al/ITO, ITO/AlNiLa/ITO, or ITO/AlNiLa.

8. The display device as claimed in claim 1, wherein the source/drain electrodes include one or more of aluminum, molybdenum tungsten, molybdenum, copper, silver, and/or alloys thereof.

9. The display device as claimed in claim 8, wherein the source/drain electrodes include a multi-layer structure of MoW/AlNd/MoW, Ti/Cu/Ti, and/or Ti/Al/Ti.

10. The display device as claimed in claim 1, wherein the cover layer has a thickness of about 30 angstroms to about 50 angstroms.

11. The display device as claimed in claim 1, wherein the cover layer is directly on the source/drain electrodes.

12. The display device as claimed in claim 1, wherein the cover layer entirely overlaps with the source/drain electrodes.

13. The display device as claimed in claim 1, wherein the cover layer is non-continuous.

14. The display device as claimed in claim 1, wherein the light source is a light emitting diode.

15. The display device as claimed in claim 1, wherein the display device is an organic electroluminescent display device.

16. A method of fabricating a display device, comprising:
forming a thin film transistor (TFT) on a substrate, the TFT including source/drain electrodes;
forming a cover layer on the source/drain electrodes; and
forming a light source including at least one electrode, the electrode being electrically connected to the source/drain electrodes of the TFT through the cover layer,
wherein the cover layer includes a same material as the electrode of the light source.

17. The method as claimed in claim 16, wherein forming the TFT includes forming the source/drain electrodes by depositing a first conductive layer on the substrate in a first chamber, and forming the cover layer includes depositing a second conductive layer on the first conductive layer in the first chamber.

18. The method as claimed in claim 17, wherein forming the light source includes forming the at least one electrode by depositing a third conductive layer on the second conductive layer in a second chamber, the second chamber being different than the first chamber.

19. The method as claimed in claim 16, wherein the cover layer and the electrode of the light source are formed of a same conductive material, the conductive material including one or more of indium-tin-oxide, indium-zinc-oxide, indium-zinc-tin-oxide, indium-cesium-oxide, and/or indium-tungsten-oxide.

20. The method as claimed in claim 16, wherein forming the light source includes forming a light emitting diode.
